(19) United States
(12) Patent Application Publication
(10) Pub. No.: US 2024/0096815 A1
(43) Pub. Date: Mar. 21, 2024

(54) SEMICONDUCTOR PACKAGE

(71) Applicant: SAMSUNG ELECTRONICS CO., LTD., Suwon-si (KR)

(72) Inventors: Jaegwon JANG, Suwon-si (KR); Inhyung SONG, Suwon-si (KR); Yeonho JANG, Suwon-si (KR)

(73) Assignee: SAMSUNG ELECTRONICS CO., LTD., Suwon-si (KR)

(21) Appl. No.: 18/244,739

(22) Filed: Sep. 11, 2023

(30) Foreign Application Priority Data
Sep. 15, 2022 (KR) 10-2022-0116634

(51) Int. Cl. H01L 23/544; H01L 23/498; H01L 25/10; H01L 25/16

(52) U.S. Cl. CPC H01L 23/544; H01L 23/49822; H01L 25/105; H01L 25/16; H01L 24/48; H01L 2223/54426; H01L 2225/1023; H01L 2225/1041; H01L 2225/1058

(57) ABSTRACT

A semiconductor package includes: a first package substrate including a first redistribution structure; a second package substrate including a second redistribution structure; a semiconductor chip provided between the first package substrate and the second package substrate, and attached to the first package substrate; and a fiducial mark provided on the second package substrate and separated from the second redistribution structure in a plan view.

### CROSS-REFERENCE TO RELATED APPLICATION

This application is based on and claims priority under 35 U.S.C. § 119 to Korean Patent Application No. 10-2022-0116634, filed on Sep. 15, 2022, in the Korean Intellectual Property Office, the disclosure of which is incorporated by reference herein in its entirety.

### BACKGROUND

The present disclosure relates to a semiconductor package.

Electronic devices are getting smaller and lighter according to the rapid development of the electronics industry and the needs of users, and accordingly, high integration of semiconductor chips, which are core components of the electronic devices, is needed. In order to cope with this trend, a semiconductor package structure, in which several semiconductor chips are stacked on one package substrate or an interposer substrate may be provided arranged between semiconductor chips. In addition, a stacked semiconductor package structure may be provided, in which a second semiconductor package structure is stacked on a first semiconductor package structure.

### SUMMARY

One or more example embodiments provide a semiconductor package with improved reliability.

One or more example embodiments also provide a semiconductor package that may reduce misalignment between a lower package and an upper package.

According to an aspect of an example embodiment, a semiconductor package includes: a first package substrate including a first redistribution structure; a second package substrate including a second redistribution structure; a semiconductor chip provided between the first package substrate and the second package substrate, and attached to the first package substrate; and a fiducial mark provided on the second package substrate and separated from the second redistribution structure in a plan view.

According to an aspect of an example embodiment, a semiconductor package includes: a semiconductor chip having an active surface and an inactive surface opposite to the active surface; a first package substrate provided on the active surface, the first package substrate including a first base insulating layer and a first redistribution structure; a second package substrate provided on the inactive surface, the second package substrate including a second base insulating layer and a second redistribution structure; a plurality of upper surface pads provided on an upper surface of the second package substrate; a plurality of lower surface pads provided on a lower surface of the second package substrate; and a fiducial mark provided on the second package substrate and provided outside the plurality of upper surface pads relative to a central portion of the second package substrate in a plan view without overlapping the second redistribution structure in a vertical direction.

According to an aspect of an example embodiment, a semiconductor package includes: a first package substrate including a first redistribution structure; a first semiconductor chip provided on the first package substrate; a plurality of conductive posts provided around the first semiconductor chip on the first package substrate; a second package substrate provided on the first semiconductor chip and electrically connected to the first package substrate through the plurality of conductive posts, the second package substrate including a second redistribution structure; a plurality of upper surface pads provided on an upper surface of the second package substrate; a plurality of fiducial marks provided on the second package substrate, and provided outside the plurality of upper surface pads relative to a central portion of the second package substrate in a plan view, the plurality of fiducial marks including an independent island shape separated from the second redistribution structure, and the plurality of fiducial marks being separated from each other relative to the central portion of the second package substrate; a third package substrate electrically connected to the second package substrate through a plurality of conductive connection terminals respectively provided on the plurality of upper surface pads; and a second semiconductor chip provided on the third package substrate.

### BRIEF DESCRIPTION OF THE DRAWINGS

The above and other aspects and features will be more apparent from the following description of one or more example embodiments taken in conjunction with the accompanying drawings, in which:

FIG. 1 is a cross-sectional view illustrating a semiconductor package according to one or more example embodiments;

FIG. 2 is an enlarged view of a region P1 in FIG. 1 according to one or more example embodiments;

FIG. 3 is a plan view illustrating arrangement of fiducial marks in a semiconductor package according to one or more example embodiments;

FIG. 4 is an enlarged layout view of a region P2 in FIG. 3 according to one or more example embodiments;

FIG. 5 is a cross-sectional view illustrating a semiconductor package according to one or more example embodiments;

FIG. 6 is an enlarged layout view of a region P3 in FIG. 5 according to one or more example embodiments;

FIGS. 7, 8 and 9 are perspective views illustrating arrangements and shapes of a fiducial mark and a dummy pattern according to one or more example embodiments;

FIG. 10 is a cross-sectional view of a semiconductor package according to one or more example embodiments and is an enlarged view of a region corresponding to the region P3 in FIG. 5 according to one or more example embodiments;

FIG. 11 is a cross-sectional view of a semiconductor package according to one or more example embodiments and is an enlarged view of a region corresponding to the region P3 in FIG. 5 according to one or more example embodiments;

FIG. 12 is a cross-sectional view of a semiconductor package according to one or more example embodiments and is an enlarged view of a region corresponding to the region P3 in FIG. 5 according to one or more example embodiments;

FIG. 13 is a cross-sectional view of a semiconductor package according to one or more example embodiments and is an enlarged view of a region corresponding to the region P3 in FIG. 5 according to one or more example embodiments;

FIG. 14 is a cross-sectional view illustrating a semiconductor package of a package-on-package type in which an upper package is stacked on a lower package, according to one or more example embodiments; and

FIG. 15 is a cross-sectional view illustrating a semiconductor package of a package-on-package type in which an upper package is stacked on a lower package, according to one or more example embodiments.

### DETAILED DESCRIPTION

Hereinafter, example embodiments will be described in detail with reference to the accompanying drawings. The same reference numerals are used for the same components in the drawings, and redundant descriptions thereof are omitted.

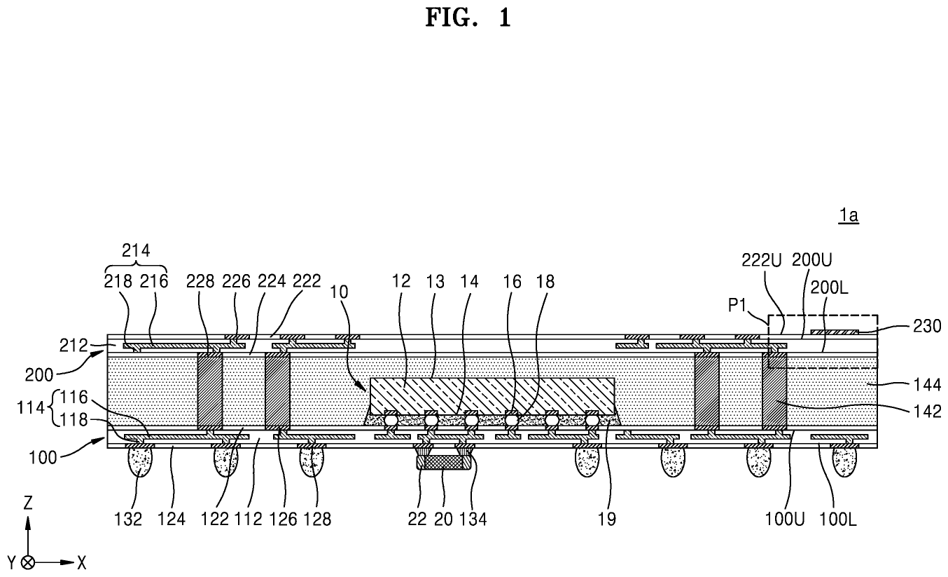

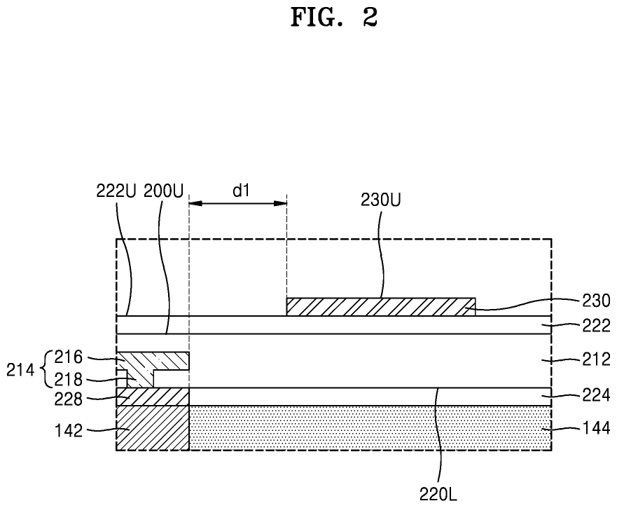

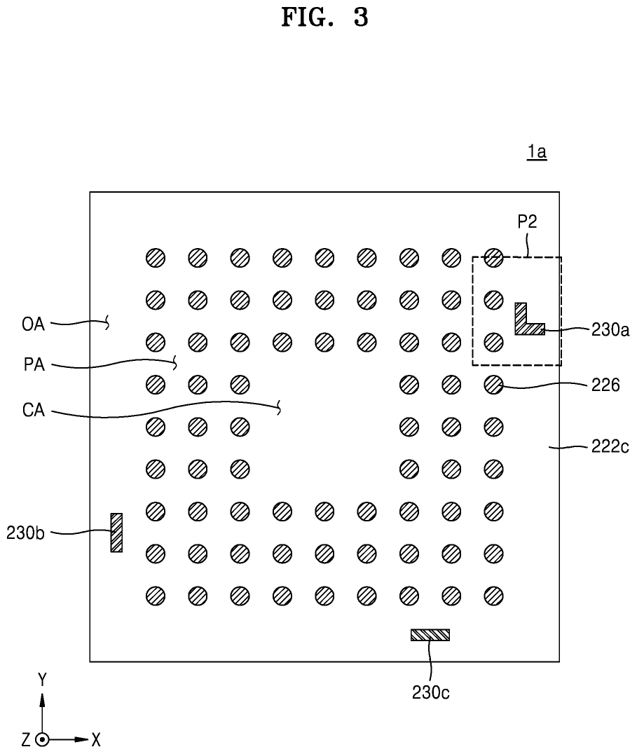

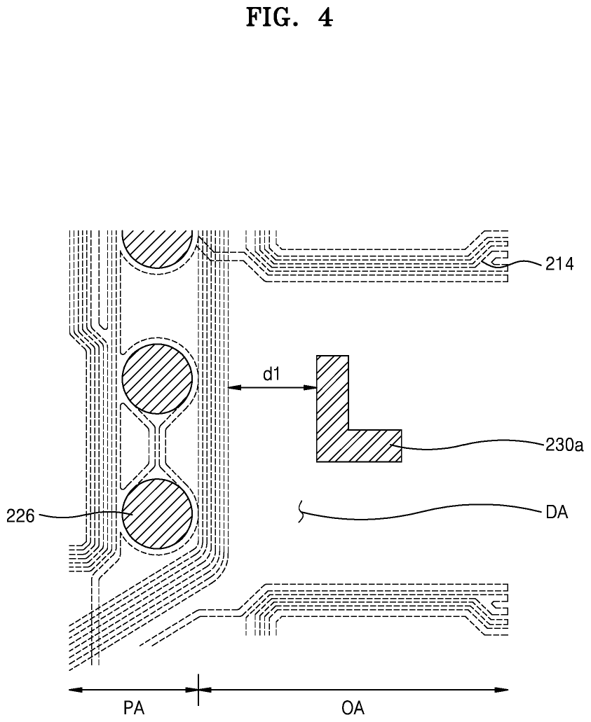

FIG. 1 is a cross-sectional view illustrating a semiconductor package 1a according to one or more example embodiments. FIG. 2 is an enlarged view of a region P1 in FIG. 1, according to one or more example embodiments. FIG. 3 is a plan view illustrating an arrangement of fiducial marks 230 in the semiconductor package 1a according to one or more example embodiments. FIG. 4 is an enlarged layout view of a region P2 in FIG. 3, according to one or more example embodiments.

Referring to FIGS. 1, 2, 3 and 4, the semiconductor package 1a includes a first package substrate 100, a first semiconductor chip 10 on the first package substrate 100, and a second package substrate 200 covering the first semiconductor chip 10.

As semiconductor chips are reduced in size, and/or the number of input and output terminals is increased, there is a limit to accommodating all of the input and output terminals on a main surface of a semiconductor chip. The semiconductor package 1a according to one or more example embodiments may be a fan-out package extending to an outer circumferential region of the first semiconductor chip 10 to have input and output terminals provided in the semiconductor package 1a. In addition, the semiconductor package 1a may have a structure of a fan out wafer level package (FOWLP) or a fan out panel level package (FOPLP) manufactured at a wafer level or a panel level.

According to one or more example embodiments, the first package substrate 100 may include a first base insulating layer 112 and a first redistribution structure 114 within the first base insulating layer 112. According to one or more example embodiments, the first redistribution structure 114 may include a plurality of first redistribution patterns 116 extending in a horizontal direction (the X direction and/or the Y direction) within the first base insulating layer 112, and a plurality of first redistribution vias 118 partially extending in the first base insulating layer 112 in a vertical direction (the Z direction).

For example, the first base insulating layer 112 may include a plurality of first sub-base insulating layers. For example, the plurality of first redistribution patterns 116 may be provided on upper and/or lower surfaces of the plurality of first sub-base insulating layers. For example, the plurality of first redistribution vias 118 may extend in the plurality of first sub-base insulating layers in the vertical direction (the Z direction).

According to one or more example embodiments, the first base insulating layer 112 may comprise at least one material selected from: a phenol resin, an epoxy resin, and polyimide. For example, the first base insulating layer 112 may include, but is not limited to, flame retardant 4 (FR4), tetrafunctional epoxy, polyphenylene ether, epoxy/polyphenylene oxide, bismaleimide triazine (BT), thermount, cyanate ester, polyimide, and liquid crystal polymer, or a combination thereof.

According to one or more example embodiments, the first redistribution structure 114 may include, but is not limited to, copper (Cu), nickel (Ni), aluminum (Al), silver (Ag), gold (Au), chromium (Cr), titanium (Ti), palladium (Pd), or a combination thereof. For example, each of the plurality of first redistribution patterns 116 and the plurality of first redistribution vias 118 may include, but is not limited to, at least one of electrolytically deposited (ED) copper foil, rolled-annealed (RA) copper foil, ultra-thin copper foil, sputtered copper, a copper alloy, or similar materials.

In one or more example embodiments, the first package substrate 100 may comprise a printed circuit board. For example, the first package substrate 100 may comprise a multi-layer printed circuit board.

According to one or more example embodiments, a plurality of first upper surface pads 126 electrically connected to the first redistribution structure 114 may be on an upper surface 100U of the first package substrate 100, and a plurality of first lower surface pads 128 electrically connected to the first redistribution structure 114 may be on a lower surface 100L of the first package substrate 100. According to one or more example embodiments, the semiconductor package 1a may further include a first upper insulating layer 122 covering the upper surface 100U of the first package substrate 100. The plurality of first upper surface pads 126 may be provided in the first upper insulating layer 122. The semiconductor package 1a may further include a first lower insulating layer 124 covering the lower surface 100L of the first package substrate 100. The plurality of first lower surface pads 128 may be provided in the first lower insulating layer 124. The first upper insulating layer 122 and the first lower insulating layer 124 may respectively insulate areas between the plurality of first upper surface pads 126 and areas between the plurality of first lower surface pads 128. In one or more example embodiments, each of the first upper insulating layer 122 and the first lower insulating layer 124 may comprise a solder resist layer. In one or more example embodiments, the first upper insulating layer 122 and the first lower insulating layer 124 may comprise the same material as the first base insulating layer 112. In one or more example embodiments, the first upper insulating layer 122 and the first lower insulating layer 124 may be formed integrally with the first base insulating layer 112.

According to one or more example embodiments, each of the plurality of first upper surface pads 126 and the plurality of first lower surface pads 128 may include, but is not limited to, copper (Cu), nickel (Ni), aluminum (Al), silver (Ag), gold (Au), chromium (Cr), titanium (Ti), palladium (Pd), or a combination thereof. For example, each of the plurality of first upper surface pads 126 and the plurality of first lower surface pads 128 may comprise ED copper foil, RA copper foil, ultra-thin copper foil, sputtered copper, a copper alloy, or similar materials.

According to one or more example embodiments, a plurality of first external connection terminals 132 may be bonded to at least some of the plurality of first lower surface pads 128. For example, the plurality of first external connection terminals 132 may electrically connect the semiconductor package 1a to a mother board or other external device.

According to one or more example embodiments, the first semiconductor chip 10 may include a first semiconductor substrate 12 having an active surface 14 and an inactive surface 13 opposite to the active surface 14. The first semiconductor chip 10 may comprise a semiconductor device including an integrated circuit. According to one or more example embodiments, a circuit portion for implementing an integrated circuit function of the first semiconductor chip 10 may be provided on the active surface 14 of the first semiconductor substrate 12. According to one or more example embodiments, a plurality of chip pads 16 may be on a lower surface of the first semiconductor chip 10 adjacent to the active surface 14 of the first semiconductor substrate 12. Because the active surface 14 of the first semiconductor substrate 12 is very close to the lower surface of the first semiconductor chip 10, illustration of distinction between the active surface 14 of the first semiconductor substrate 12 and the lower surface of the first semiconductor chip 10 is omitted. For example, the lower surface of the first semiconductor chip 10 may be referred to as the active surface 14 of the first semiconductor substrate 12, and the upper surface of the first semiconductor chip 10 may be referred to as the inactive surface 13 of the first semiconductor substrate 12.

According to one or more example embodiments, the first semiconductor chip 10 may have a face-down arrangement in which the active surface 14 of the first semiconductor substrate 12 faces the first package substrate 100 and may be on the first package substrate 100. For example, the first semiconductor chip 10 may be attached to an upper surface of the first upper insulating layer 122, and may be attached to the upper surface 100U of the first package substrate 100 when the first upper insulating layer 122 is omitted.

According to one or more example embodiments, a plurality of chip connection members 18 may be between the plurality of chip pads 16 of the first semiconductor chip 10. The plurality of chip connection members 18 may be provided between some of the plurality of first upper surface pads 126 on the first package substrate 100. For example, the chip connection members 18 may comprise, but are not limited to, solder balls or micro bumps. For example, the first package substrate 100 may be electrically connected to the first semiconductor chip 10 through the plurality of chip connection members 18.

According to one or more example embodiments, a first underfill layer 19 may be between the lower surface of the first semiconductor chip 10 and the upper surface of the first upper insulating layer 122. For example, the first underfill layer 19 may cover the plurality of chip connection members 18. For example, the first underfill layer 19 may comprise a resin material formed by a capillary underfill method.

According to one or more example embodiments, the first semiconductor substrate 12 may include a semiconductor material, including, but not limited to, silicon (Si) or germanium (Ge). According to one or more example embodiments, the first semiconductor substrate 12 may include a compound semiconductor material, including, but not limited to, silicon carbide (SiC), gallium arsenide (GaAs), indium arsenide (InAs), or indium phosphide (InP). For example, the first semiconductor substrate 12 may include a conductive region, including, but not limited to, a well doped with an impurity and may have various device isolation structures, including, but not limited to, a shallow trench isolation (STI) structure.

In one or more example embodiments, the first semiconductor chip 10 may include a logic chip. For example, the first semiconductor chip 10 may include, but is not limited to, a central processing unit (CPU) chip, a graphics processing unit (GPU) chip, or an application processor (AP) chip. In one or more example embodiments, the first semiconductor chip 10 may include a memory semiconductor chip. For example, the first semiconductor chip 10 may include a nonvolatile semiconductor memory chip including, but not limited to, flash memory, phase-change random access memory (PRAM), magnetic random access memory (MRAM), ferroelectric random access memory (FeRAM), or resistive random access memory (RRAM). The flash memory may include, for example, a NAND flash memory or a V-NAND flash memory. For example, the first semiconductor chip 10 may also include a volatile semiconductor memory chip including a dynamic random access memory (DRAM) or a static random access memory (SRAM).

According to one or more example embodiments, the semiconductor package 1a may further include an auxiliary chip 20 attached below the first package substrate 100. For example, the auxiliary chip 20 may be different in kind from the first semiconductor chip 10. For example, the auxiliary chip 20 may have a smaller horizontal width and a smaller horizontal area than the first semiconductor chip 10, which is a main semiconductor chip. The auxiliary chip 20 may assist an operation of the first semiconductor chip 10. For example, the auxiliary chip 20 may include, but is not limited to, a silicon capacitor, a controller chip, or a semiconductor memory chip.

According to one or more example embodiments, the auxiliary chip 20 may have a plurality of auxiliary chip terminals 22. According to one or more example embodiments, a plurality of auxiliary chip connection terminals 134 may be between the plurality of auxiliary chip terminals 22 and at least some of the plurality of first lower surface pads 128. For example, the plurality of auxiliary chip connection terminals 134 may electrically connect the auxiliary chip 20 to the first package substrate 100.

According to one or more example embodiments, the second package substrate 200 may cover the first semiconductor chip 10 on the first package substrate 100. According to one or more example embodiments, the second package substrate 200 may be separated from the first semiconductor chip 10 in the vertical direction (the Z direction).

According to one or more example embodiments, the second package substrate 200 may include a second base insulating layer 212 and a second redistribution structure 214 in the second base insulating layer 212. According to one or more example embodiments, the second redistribution structure 214 may include a plurality of second redistribution patterns 216 extending in the horizontal direction (the X direction and/or the Y direction) in the second base insulating layer 212, and a plurality of second redistribution vias 218 partially extending in the second base insulating layer 212 in the vertical direction (the Z direction).

For example, the second base insulating layer 212 may include a plurality of second sub-base insulating layers. For example, the plurality of second redistribution patterns 216 may be provided on upper or lower surfaces of the plurality of second sub-base insulating layers. For example, the plurality of second redistribution vias 218 may respectively extend in the plurality of second sub-base insulating layers in the vertical direction (the Z direction).

According to one or more example embodiments, the second base insulating layer 212 may comprise, but is not limited to, at least one material selected from a phenol resin, an epoxy resin, and polyimide. For example, the second base insulating layer 212 may include, but is not limited to, flame retardant 4 (FR4), tetrafunctional epoxy, polyphenylene ether, epoxy/polyphenylene oxide, bismaleimide triazine (BT), thermount, cyanate ester, polyimide, and liquid crystal polymer or a combination thereof. According to one or more example embodiments, the second base insulating layer 212 may include a light-transmitting organic layer. According to one or more example embodiments, the second base insulating layer 212 may be implemented by a photo imageable dielectric (PID) layer.

According to one or more example embodiments, the second redistribution structure 214 may include, but is not limited to, copper (Cu), nickel (Ni), aluminum (Al), silver (Ag), gold (Au), chromium (Cr), titanium (Ti), palladium (Pd), or a combination thereof. For example, each of the plurality of second redistribution patterns 216 and the plurality of second redistribution vias 218 may include, but are not limited to, electrolytically deposited (ED) copper foil, rolled-annealed (RA) copper foil, ultra-thin copper foil, sputtered copper, a copper alloy, or other similar materials.

According to one or more example embodiments, a plurality of second upper surface pads 226 may be electrically connected to the second redistribution structure 214 and may be on an upper surface 200U of the second package substrate 200. A plurality of second lower surface pads 228 electrically connected to the second redistribution structure 214 may be on a lower surface 200L of the second package substrate 200. According to one or more example embodiments, the semiconductor package 1a may further include a second upper insulating layer 222 covering the upper surface 200U of the second package substrate 200. The plurality of second upper surface pads 226 may extend in the second upper insulating layer 222. A second lower insulating layer 224 may cover the lower surface 200L of the second package substrate 200. The plurality of second lower surface pads 228 may be provided in the second lower insulating layer 224. For example, the second upper insulating layer 222 and the second lower insulating layer 224 may respectively insulate between the plurality of second upper surface pads 226 and between the plurality of second lower surface pads 228. For example, the second upper insulating layer 222 and the second lower insulating layer 224 may each function as a solder resist.

According to one or more example embodiments, each of the second upper insulating layer 222 and the second lower insulating layer 224 may comprise, but is not limited to, at least one material selected from a phenol resin, an epoxy resin, and polyimide. For example, each of the second upper insulating layer 222 and the second lower insulating layer 224 may include, but is not limited to, flame retardant 4 (FR4), tetrafunctional epoxy, polyphenylene ether, epoxy/polyphenylene oxide, bismaleimide triazine (BT), thermount, cyanate ester, polyimide, and liquid crystal polymer or a combination thereof. According to one or more example embodiments, the second base insulating layer 212 may include a light-transmitting organic layer. According to one or more example embodiments, the second upper insulating layer 222 and the second lower insulating layer 224 may comprise the same material as the second base insulating layer 212. In one or more example embodiments, the second upper insulating layer 222 and the second lower insulating layer 224 may be formed integrally with the second base insulating layer 212.

According to one or more example embodiments, each of the plurality of second upper surface pads 226 and each of the plurality of second lower surface pads 228 may include, but is not limited to, copper (Cu), nickel (Ni), aluminum (Al), silver (Ag), gold (Au), chromium (Cr), titanium (Ti), palladium (Pd), or a combination thereof. For example, each of the plurality of second upper surface pads 226 and the plurality of second lower surface pads 228 may comprise, but is not limited to, electrolytically deposited (ED) copper foil, rolled-annealed (RA) copper foil, ultra-thin copper foil, sputtered copper, a copper alloy, or similar materials.

According to one or more example embodiments, a first molding layer 144 may be between the first package substrate 100 and the second package substrate 200. According to one or more example embodiments, the first molding layer 144 may seal an upper surface of the first upper insulating layer 122 on the first package substrate 100, a lower surface of the second lower insulating layer 224 below the second package substrate 200, the first semiconductor chip 10, and the first underfill layer 19. According to one or more example embodiments, the first molding layer 144 may comprise, but is not limited to, an epoxy-based molding resin, a polyimide-based molding resin, or similar materials. For example, the first molding layer 144 may comprise a molding member including an epoxy mold compound (EMC).

According to one or more example embodiments, the semiconductor package 1a may include a plurality of conductive posts 142 extending in the first molding layer 144 in the vertical direction (the Z direction) between the first package substrate 100 and the second package substrate 200. According to one or more example embodiments, the plurality of conductive posts 142 may be separated from the first semiconductor chip 10 in the horizontal direction (the X direction and/or the Y direction). According to one or more example embodiments, the plurality of conductive posts 142 may be respectively in contact with upper surfaces of the plurality of first upper surface pads 126 and lower surfaces of the plurality of second lower surface pads 228, and may electrically connect the first package substrate 100 to the second package substrate 200. According to one or more example embodiments, the plurality of conductive posts 142 may comprise, but are not limited to, copper (Cu), copper-tin (CuSn), copper-manganese (CuMg), copper-nickel (CuNi), copper-zinc (CuZn), copper-lead (CuPd), copper-gold (CuAu), copper-tungsten (CuW), tungsten (W), or an alloy thereof.

According to one or more example embodiments, the semiconductor package 1a may include a fiducial mark 230 on the second package substrate 200. According to one or more example embodiments, the fiducial mark 230 may be on an upper surface 222U of the second upper insulating layer 222. In one or more example embodiments, when the semiconductor package 1a does not include the second upper insulating layer 222, the fiducial mark 230 may be on the upper surface 200U of the second package substrate 200.

For example, the fiducial mark 230 may be configured as a fiducial point that helps align packages with one another. For example, when another semiconductor package is stacked on the semiconductor package 1a, the fiducial mark 230 may be configured as a fiducial point for distinguishing rotation coordinates in the horizontal direction (the X direction and/or the Y direction) between different semiconductor packages. For example, the fiducial mark 230 may be recognizable by an optical camera. According to one or more example embodiments, the semiconductor package 1a may be a lower package of a semiconductor package of a package-on-package (PoP) type.

According to one or more example embodiments, the fiducial mark 230 may be outside the plurality of second upper surface pads 226 relative to a central portion of the second package substrate 200. For example, in a plan view, the second package substrate 200 may include a central region CA, which is a region overlapping the first semiconductor chip 10 in the vertical direction (the Z direction). The second package substrate 200 may further include a pad region PA in which the plurality of second upper surface pads 226 surrounding the central region CA are provided. The second package substrate 200 may also include an outer region OA, which is a region outside the pad region PA relative to the central region CA. According to one or more example embodiments, the fiducial mark 230 may be provided in the outer region OA on the second package substrate 200.

According to one or more example embodiments, the fiducial mark 230 may be separated from the second redistribution structure 214 in a plan view. According to one or more example embodiments, the fiducial mark 230 may be separated from the second redistribution structure 214 in the horizontal direction (the X direction and/or the Y direction) by a first separation distance d1 in a plan view. According to one or more example embodiments, in a plan view, the fiducial mark 230 may have an independent island shape separated from the second redistribution structure 214 and surrounded by the second redistribution structure 214 (see FIG. 4). For example, in a plan view, a separation region DA which does not include the second redistribution structure 214 may be formed in the outer region OA of the second package substrate 200, and the fiducial mark 230 may be provided in the separation region DA. Accordingly, it may be possible to prevent a problem in which a recognition rate of an optical camera for the fiducial mark 230 is reduced due to the light reflected by the second redistribution structure 214.

According to one or more example embodiments, in a plan view, the fiducial mark 230 may be separated from the second redistribution structure 214 by 100 μm or more in the horizontal direction (the X direction and/or the Y direction). Accordingly, a recognition rate of an optical camera for the fiducial mark 230 may be improved, and when a plurality of semiconductor packages are stacked, the semiconductor package 1a may be prevented from being misaligned with the other semiconductor packages.

According to one or more example embodiments, an upper surface 230U of the fiducial mark 230 may have a uniform surface roughness. In one or more example embodiments, the upper surface 230U of the fiducial mark 230 may have a smooth planar shape. In one or more example embodiments, the upper surface 230U of the fiducial mark 230 may have a regular pattern shape. For example, the upper surface 230U of the fiducial mark 230 may have a regular unevenness structure. Accordingly, the fiducial mark 230 may be accurately measured or recognized.

According to one or more example embodiments, the fiducial mark 230 may have an asymmetric planar shape. According to one or more example embodiments, the asymmetric planar shape may indicate a shape of which a rotated angle is easily recognized when rotation is made about a rotation axis that vertically penetrates a plane. For example, the fiducial mark 230 may have a shape, including, but not limited to, a clamp shape or a rectangular shape having a long axis and a short axis. For example, the fiducial mark 230 may not have a circular planar shape and may not have a regular polygonal planar shape.

According to one or more example embodiments, the fiducial mark 230 may be apart from the plurality of second upper surface pads 226, in a plan view. The fiducial mark 230, for example, may have different planar shape from the plurality of second upper surface pads 226. The fiducial mark is not only spaced apart from the second redistribution structure 214 in a plan view, but also electrically insulated from the second redistribution structure 214, and here, the fiducial mark 230 may be referred to as a dummy pad.

According to one or more example embodiments, the semiconductor package 1a may include a plurality of fiducial marks 230. Although one or more example embodiments shown in FIG. 3 illustrate that the semiconductor package 1a includes three fiducial marks 230a, 230b, and 230c, the semiconductor package 1a may include two or more fiducial marks 230. However, the number of fiducial marks is not limited thereto, and the semiconductor package 1a may also include one fiducial mark 230 consistent with one or more example embodiments.

According to one or more example embodiments, the plurality of fiducial marks 230 may be separated from each other in the outer region OA. According to one or more example embodiments, at least some of the plurality of fiducial marks 230 may be point-symmetric with respect to a central portion of the second package substrate 200.

According to one or more example embodiments, at least some of the plurality of fiducial marks 230 may have different planar shapes. According to one or more example embodiments, when the fiducial marks 230 are rotated by a rotation axis penetrating the fiducial mark 230 in the vertical direction (the Z direction), it may be understood that the fiducial marks 230 may have different planar shapes even when the fiducial marks 230 have the same shape. It may be understood that, for example, a rectangular shape in which a first length corresponding to a length in a first horizontal direction (the X direction) is longer than a second length corresponding to a length in a second horizontal direction (the Y direction) is different in planar shape from a rectangular shape in which the length in the first horizontal direction (the X direction) is equal to the second length and the length in the second horizontal direction (the Y direction) is equal to the first length according to one or more example embodiments.

According to one or more example embodiments, the fiducial mark 230 may include, but is not limited to, copper (Cu), nickel (Ni), aluminum (Al), silver (Ag), gold (Au), chromium (Cr), titanium (Ti), palladium (Pd), or combinations thereof.

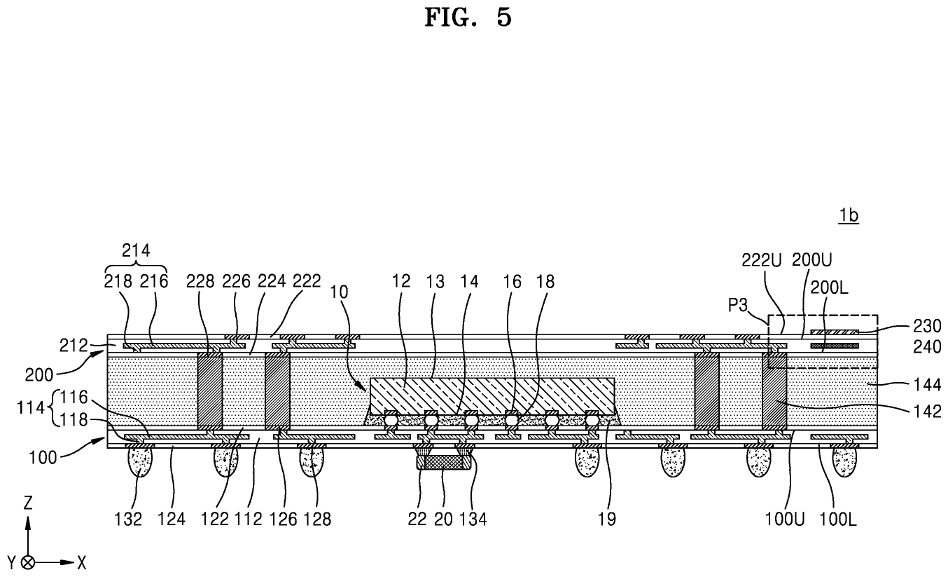

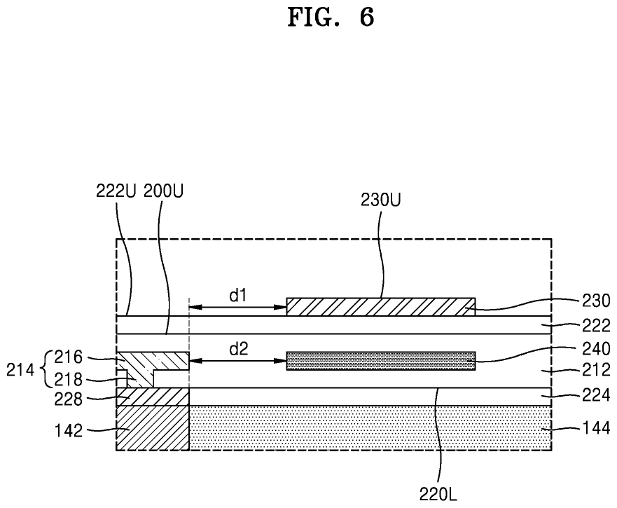

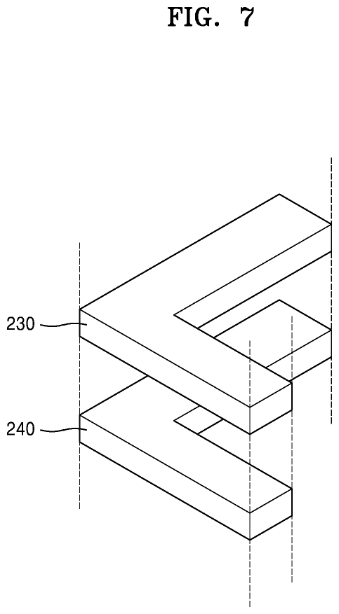

FIG. 5 is a cross-sectional view illustrating a semiconductor package 1b according to one or more example embodiments. FIG. 6 is an enlarged layout view of a region P3 in FIG. 5 according to one or more example embodiments. The region P3 according to one or more example embodiments shown in FIG. 5 may correspond to the region P1 in one or more example embodiments shown in FIG. 1. FIG. 7 is a perspective view illustrating arrangements and shapes of a fiducial mark 230 and a dummy pattern 240 according to one or more example embodiments.

Referring to FIGS. 5, 6 and 7, a second package substrate 200 may further include a dummy pattern 240 overlapping the fiducial mark 230 in the vertical direction. According to one or more example embodiments, the dummy pattern 240 may have the same planar shape as the fiducial mark 230. According to one or more example embodiments, in a plan view, the dummy pattern 240 may be separated from a second redistribution structure 214 in the horizontal direction (the X direction and/or the Y direction) by a second separation distance d2, and the second separation distance d2 may be equal to a first separation distance d1. Accordingly, an optical recognition rate of the fiducial mark 230 may be improved.

According to one or more example embodiments, the dummy pattern 240 may be separated from the fiducial mark 230 in the vertical direction (the Z direction). For example, a part of the second upper insulating layer 222 and/or a second base insulating layer 212 may be between the dummy pattern 240 and the fiducial mark 230.

According to one or more example embodiments, the dummy pattern 240 may be at the same level as the second redistribution structure 214 in the second package substrate 200 in the vertical direction (the Z direction). According to one or more example embodiments, the dummy pattern 240 may be at the same level as the second redistribution pattern 216 in the vertical direction (the Z direction). In this case, according to one or more example embodiments, the dummy pattern 240 may be formed together with the second redistribution pattern 216 during a step of forming the second redistribution pattern 216. According to one or more example embodiments, the dummy pattern 240 may be provided at the same level as a second redistribution via 218 in the vertical direction (the Z direction). In this case, according to one or more example embodiments, the dummy pattern 240 may be formed together with the second redistribution via 218 during a step of forming the second redistribution via 218.

Although FIG. 5 illustrates one or more example embodiments wherein the second package substrate 200 includes a plurality of second redistribution patterns 216 at the same level as each other in the vertical direction (the Z direction), one or more example embodiments is not limited thereto. For example, the second package substrate 200 may include the plurality of second redistribution patterns 216 at different levels in the vertical direction (the Z direction) with some of a plurality of second sub-base insulating layers constituting the second base insulating layer 212 therebetween. Similarly, the second package substrate 200 may include a plurality of second redistribution vias 218 at different levels in the vertical direction with some of the plurality of second sub-base insulating layers therebetween. In this case, according to one or more example embodiments, the dummy pattern 240 may be at the same level in the vertical direction (the Z direction) as the plurality of second redistribution patterns 216 and the plurality of second redistribution vias 218.

In one or more example embodiments, the dummy pattern 240 may include, but is not limited to, copper (Cu), nickel (Ni), aluminum (Al), silver (Ag), gold (Au), chromium (Cr), titanium (Ti), palladium (Pd), or a combination thereof.

According to one or more example embodiments, the dummy pattern 240 may have an outer boundary that is the same as an outer boundary of the fiducial mark 230. The dummy pattern 240 may have a pattern shape in which an inner portion of the outer boundary is at least partially penetrated in the vertical direction (the Z direction). According to one or more example embodiments, the dummy pattern 240 may have a regular mesh pattern shape.

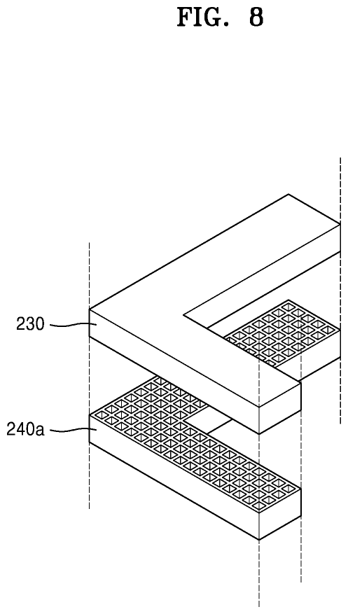

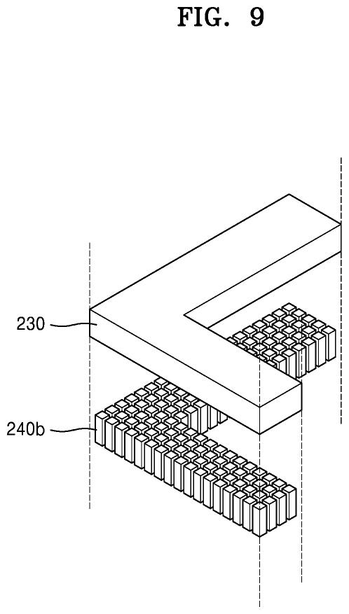

FIGS. 8 and 9 are perspective views illustrating shapes of the fiducial mark 230 and dummy patterns 240a and 240b according to one or more example embodiments. A difference between FIG. 7, FIG. 8, and FIG. 9 is that according to one or more example embodiments shown in FIGS. 8 and 9, the dummy pattern 240 has a pattern shape penetrated in the vertical direction (the Z direction).

Referring to one or more example embodiments shown in FIG. 8, the dummy pattern 240a may have a lattice pattern shape having the same outer boundary as the fiducial mark 230. Referring to one or more example embodiments shown in FIG. 9, the dummy pattern 240b may have a dot shape having the same outer boundary as the fiducial mark 230.

However, one or more example embodiments are not limited thereto, and the dummy pattern 240 may have a pattern shape partially penetrated in the vertical direction (the Z direction) and may have any shape having a regular structure.

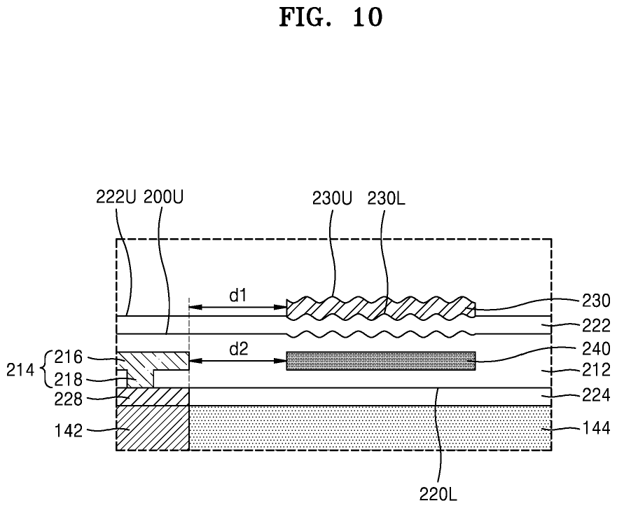

FIG. 10 is a cross-sectional view of the semiconductor package 1b according to one or more example embodiments and is an enlarged view of a region corresponding to the region P3 according to one or more example embodiments shown in FIG. 5. Specifically, FIG. 10 is a cross-sectional view of the semiconductor package 1b when the dummy pattern 240 has a regular pattern of a penetration structure or a regular pattern of surface unevenness shape and is an enlarged view of a region corresponding to the region P3 in FIG. 5.

Referring to one or more example embodiments shown in FIG. 10, a portion overlapping the dummy pattern 240 in the vertical direction (the Z direction) in an upper surface 200U of the second base insulating layer 212, and a portion overlapping the dummy pattern 240 in the vertical direction (the Z direction) in an upper surface 222U of the second upper insulating layer 222 may each have a regular surface unevenness structure. According to one or more example embodiments, an upper surface 230U and a lower surface 230L of the fiducial mark 230 may have a regular surface unevenness structure. For example, in the cross-sectional view, the upper surface 230U of the fiducial mark 230 may have a wavy shape having a uniform width in the vertical direction (the Z direction) and the horizontal direction (the X direction and/or the Y direction). Accordingly, the upper surface 230U of the fiducial mark 230 may have a uniform surface roughness, and when measuring the fiducial mark 230, an optical camera may be guided to have a uniform recognition rate with respect to the entire upper surface 230U of the fiducial mark 230.

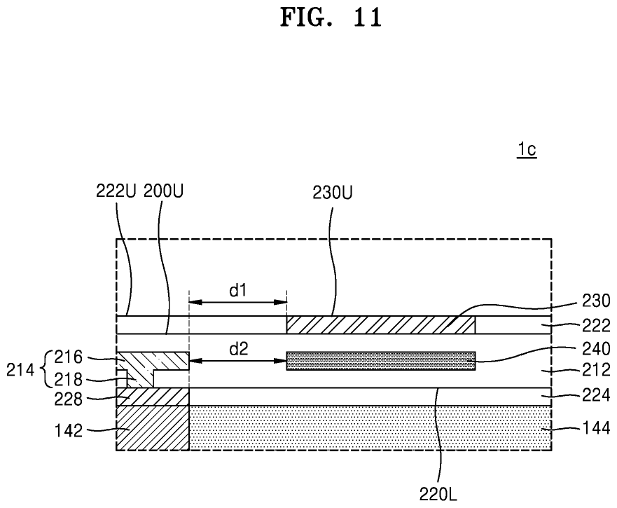

FIG. 11 is a cross-sectional view of a semiconductor package 1c according to one or more example embodiments and is an enlarged view of a region corresponding to the region P3 according to one or more example embodiments shown in FIG. 5. A difference between one or more example embodiments shown in FIG. 11 and one or more example embodiments shown in FIG. 6 is that, in FIG. 11, the fiducial mark 230 is at the same level as the second upper insulating layer 222 in the vertical direction (the Z direction).

According to one or more example embodiments, the fiducial mark 230 may be on the upper surface 200U of the second package substrate 200 in an outer region OA. According to one or more example embodiments, the second upper insulating layer 222 covers the upper surface 200U of the second package substrate 200 and exposes the fiducial mark 230 and the plurality of second upper surface pads 226. According to one or more example embodiments, the fiducial mark 230 may be at the same level as the plurality of second upper surface pads 226 in the vertical direction (the Z direction).

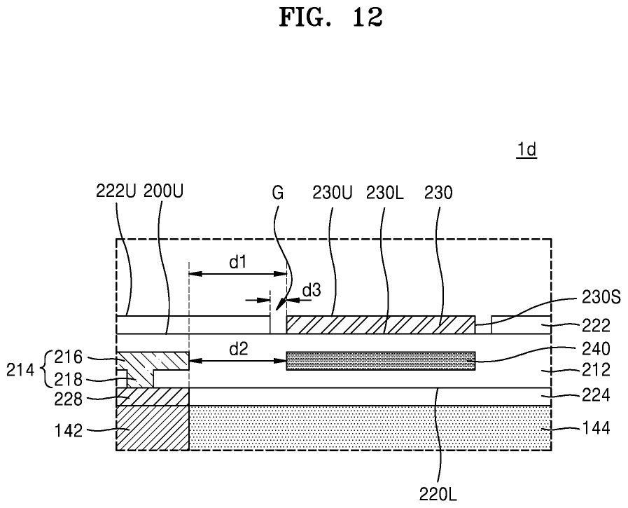

FIG. 12 is a cross-sectional view of a semiconductor package 1d according to one or more example embodiments. FIG. 12 is an enlarged view of a region corresponding to the region P3 in FIG. 5. A difference between FIG. 11 and FIG. 12 is that, in FIG. 12, a gap G is provided between the fiducial mark 230 and the second upper insulating layer 222.

Referring to one or more example embodiments shown in FIG. 12, the fiducial mark 230 may be separated from the second upper insulating layer 222 in the horizontal direction (the X direction and/or the Y direction) with the gap G therebetween. According to one or more example embodiments, the second upper insulating layer 222 may not cover a side surface 230S of the fiducial mark 230 and the second upper insulating layer 222 may be separated from the side surface 230S of the fiducial mark 230 by a third separation distance d3.

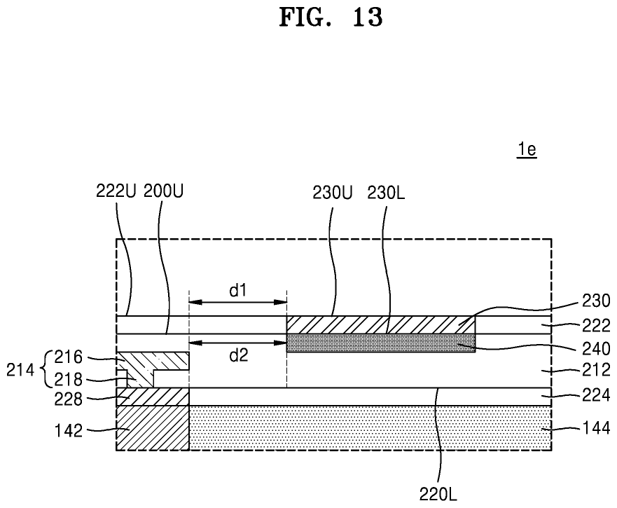

FIG. 13 is a cross-sectional view of a semiconductor package 1e according to one or more example embodiments. FIG. 13 is an enlarged view of a region corresponding to the region P3 in FIG. 5. A difference between FIG. 11 and FIG. 12, as compared to FIG. 13, is that in FIG. 13, the fiducial mark 230 is in contact with the dummy pattern 240.

Referring to one or more example embodiments shown in FIG. 13, the dummy pattern 240 may cover the lower surface 230L of the fiducial mark 230. According to one or more example embodiments, an upper surface of the dummy pattern 240 may share the same plane as the second base insulating layer 212, and the fiducial mark 230 may be stacked on the upper surface of the dummy pattern 240.

In one or more example embodiments, the fiducial mark 230 and the dummy pattern 240 may comprise the same material. For example, the fiducial mark 230 and the dummy pattern 240 may be integrally formed. In one or more example embodiments, the fiducial mark 230 and the dummy pattern 240 may comprise different materials.

Although FIG. 13 illustrates that the fiducial mark 230 is at the same level as the second upper insulating layer 222 in the vertical direction (the Z direction) and that the dummy pattern 240 overlaps the fiducial mark 230 in the second base insulating layer 212, one or more example embodiments is not limited thereto. For example, as illustrated in FIG. 5, the fiducial mark 230 may be on the upper surface 222U of the second upper insulating layer 222, and the dummy pattern 240 may be at the same level as the second upper insulating layer 222 in the vertical direction (the Z direction) and may be in contact with the fiducial mark 230.

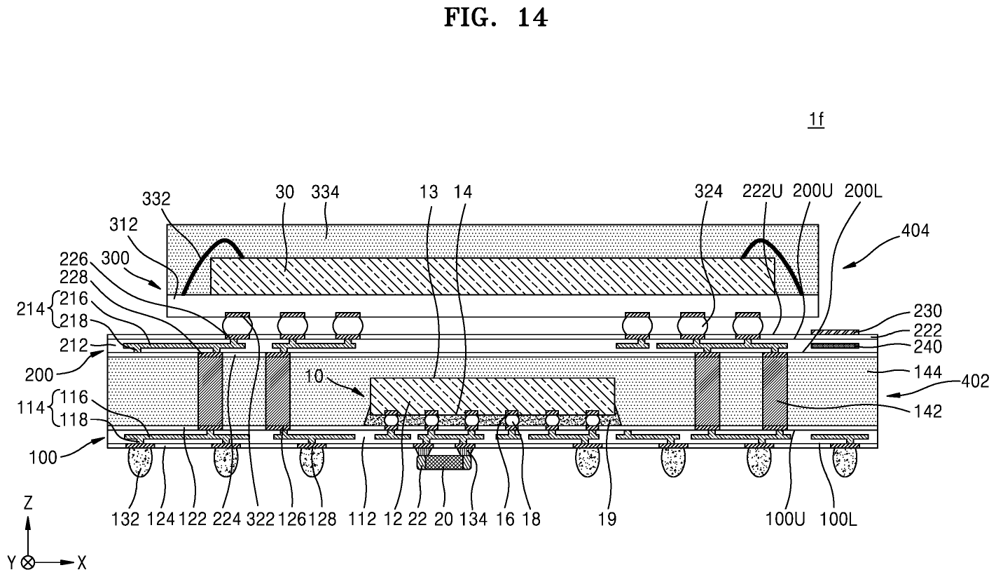

FIG. 14 is a cross-sectional view illustrating a semiconductor package if of a package-on-package type in which an upper package is stacked on a lower package, according to one or more example embodiments.

Referring to FIG. 14, the semiconductor package if may include a lower package 402 and an upper package 404. According to one or more example embodiments, the semiconductor package if may have a package-on-package type in which the upper package 404 is stacked on the lower package 402.

Although FIG. 14 illustrates one or more example embodiments wherein the lower package 402 corresponds to the semiconductor package 1b described with reference to one or more example embodiments shown in FIGS. 5, 6, 7, 8, 9 and 10, the lower package 402 may also correspond to any one of the semiconductor packages 1a described with reference to one or more example embodiments shown in FIGS. 1, 2, 3 and 4, the semiconductor package 1c described with reference to one or more example embodiments shown in FIG. 11, the semiconductor package 1d described with reference to one or more example embodiments shown in FIG. 12, and the semiconductor package 1e described with reference to one or more example embodiments shown in FIG. 13.

According to one or more example embodiments, the upper package 404 may be on the lower package 402. According to one or more example embodiments, the upper package 404 may include a third package substrate 300 and a second semiconductor chip 30 on the third package substrate 300.

According to one or more example embodiments, the third package substrate 300 may comprise a printed circuit board. According to one or more example embodiments, the third package substrate 300 may include a third base insulating layer 312 comprising at least one material selected from a phenol resin, an epoxy resin, and polyimide. According to one or more example embodiments, internal wires may be provided in the third base insulating layer 312. According to one or more example embodiments, the internal wires may be electrically connected to the second semiconductor chip 30 through bonding wires 332 and may be connected to a plurality of third lower surface pads 322 exposed on a lower surface of the third package substrate 300.

According to one or more example embodiments, a plurality of second external connection terminals 324 may be between a second package substrate 200 and the third package substrate 300. According to one or more example embodiments, the plurality of second external connection terminals 324 may be in contact with a plurality of second upper surface pads 226 exposed on the upper surface 222U of the second upper insulating layer 222 and a plurality of third lower surface pads 322 exposed on the lower surface of the third package substrate 300. Accordingly, the second package substrate 200 may be electrically connected to the third package substrate 300.

According to one or more example embodiments, a second molding layer 334 sealing the second semiconductor chip 30 and the bonding wires 332 may be provided on the third package substrate 300. According to one or more example embodiments, the second molding layer 334 may comprise an epoxy-based molding resin, a polyimide-based molding resin, or similar materials. For example, the second molding layer 334 may be a molding member including an EMC.

Although FIG. 14 illustrates that the third package substrate 300 is electrically connected to the second semiconductor chip 30 through the bonding wires 332, one or more example embodiments is not limited thereto. For example, the second semiconductor chip 30 may also be electrically connected to the third package substrate 300 through a plurality of chip connection members, including, but not limited to, solder balls, by using a flip chip bonding method like the first semiconductor chip 10.

According to one or more example embodiments, the first semiconductor chip 10 may be the same type as the second semiconductor chip 30. According to one or more example embodiments, the first semiconductor chip 10 may be a different type from the second semiconductor chip 30. For example, when the first semiconductor chip 10 is a logic chip, the second semiconductor chip 30 may be a memory chip. According to one or more example embodiments, the second semiconductor chip 30 may be implemented as a high bandwidth memory (HBM) memory chip. In one or more example embodiments, the upper package 404 may include a plurality of second semiconductor chips 30. According to one or more example embodiments, the semiconductor package if may be configured such that components, including, but not limited to, different types of semiconductor chips and passive elements, are electrically connected to each other to operate as one system.

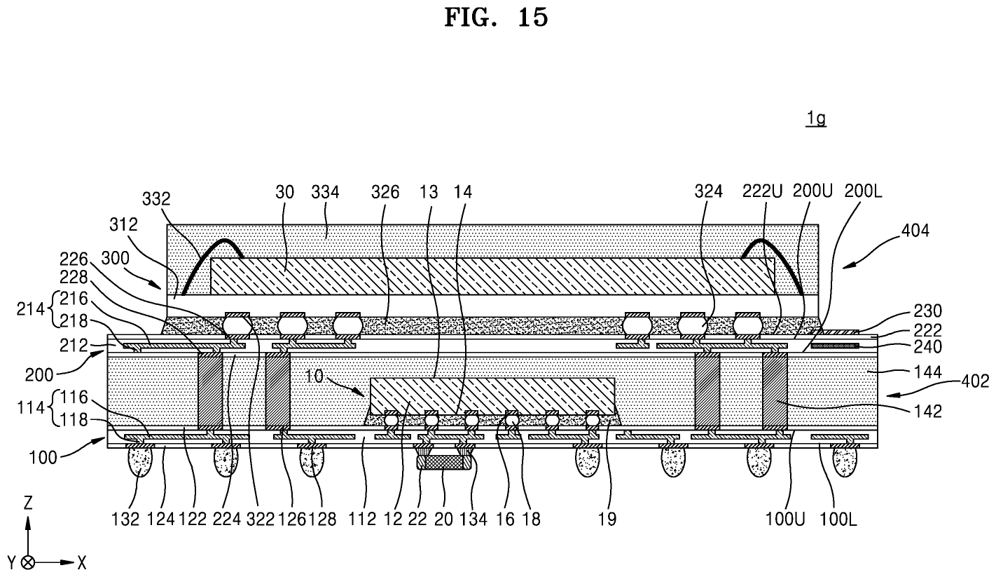

FIG. 15 is a cross-sectional view illustrating a semiconductor package 1g of a package-on-package type in which an upper package is stacked on a lower package, according to one or more example embodiments. A difference between FIG. 15 and FIG. 14 is that, in FIG. 15, a second underfill layer 326 is interposed between the lower package 402 and the upper package 404.

Referring to FIG. 15, a second underfill layer 326 is provided between a lower package 402 and an upper package 404. According to one or more example embodiments, the second underfill layer 326 may be provided between an upper surface 222U of a second upper insulating layer 222 on the second package substrate 200 and a lower surface of the third package substrate 300 and may cover a plurality of second external connection terminals 324. According to one or more example embodiments, the second underfill layer 326 may comprise a resin material formed by a capillary underfill method.

According to one or more example embodiments, the upper package 404 may have less planar area than the lower package 402. According to one or more example embodiments, the second underfill layer 326 may partially cover an upper surface of the lower package 402. According to one or more example embodiments, the second underfill layer 326 may partially cover the upper surface 222U of the second upper insulating layer 222 and may cover the fiducial mark 230 on the second upper insulating layer 222.

Although FIG. 15 illustrates that the second underfill layer 326 partially covers the fiducial mark 230, one or more example embodiments is not limited thereto. In one or more example embodiments, the second underfill layer 326 may not cover the fiducial mark 230. In one or more example embodiments, the second underfill layer 326 may also completely cover the fiducial mark 230.

While one or more example embodiments have been particularly shown and described above, it will be apparent to those skilled in the art that various changes in form and details may be made therein without departing from the spirit and scope of the following claims.

What is claimed is:

1. A semiconductor package comprising:
a first package substrate comprising a first redistribution structure;
a second package substrate comprising a second redistribution structure;
a semiconductor chip provided between the first package substrate and the second package substrate, and attached to the first package substrate; and
a fiducial mark provided on the second package substrate and separated from the second redistribution structure in a plan view.

2. The semiconductor package of claim 1, wherein the fiducial mark has a uniform surface roughness.

3. The semiconductor package of claim 1, further comprising an upper insulating layer provided on the second package substrate,
wherein the fiducial mark is provided on the upper insulating layer.

4. The semiconductor package of claim 1, further comprising an upper insulating layer provided on the second package substrate,
wherein the fiducial mark and the upper insulating layer are provided at a same level in a vertical direction.

5. The semiconductor package of claim 1, wherein the second package substrate further comprises a dummy pattern overlapping the fiducial mark in a vertical direction.

6. The semiconductor package of claim 5, wherein the fiducial mark is provided on an upper surface of the dummy pattern.

7. The semiconductor package of claim 5, wherein the dummy pattern is separated from the fiducial mark in the vertical direction.

8. The semiconductor package of claim 5, wherein the dummy pattern has one of a lattice structure and a dot structure.

9. The semiconductor package of claim 1, further comprising a plurality of fiducial marks including the fiducial mark,
wherein at least two of the plurality of fiducial marks are point-symmetric with respect to a central portion of the second package substrate.

10. The semiconductor package of claim 1, further comprising a plurality of fiducial marks including the fiducial mark, and
wherein at least two of the plurality of fiducial marks have different planar shapes.

11. A semiconductor package comprising:
a semiconductor chip having an active surface and an inactive surface opposite to the active surface;
a first package substrate provided on the active surface, the first package substrate comprising a first base insulating layer and a first redistribution structure;
a second package substrate provided on the inactive surface, the second package substrate comprising a second base insulating layer and a second redistribution structure;
a plurality of upper surface pads provided on an upper surface of the second package substrate;
a plurality of lower surface pads provided on a lower surface of the second package substrate; and
a fiducial mark provided on the second package substrate and provided outside the plurality of upper surface pads relative to a central portion of the second package substrate in a plan view without overlapping the second redistribution structure in a vertical direction.

12. The semiconductor package of claim 11, wherein the fiducial mark has an independent island shape separated from the second redistribution structure in a plan view.

13. The semiconductor package of claim 11, wherein the second base insulating layer comprises a light-transmitting organic layer.

14. The semiconductor package of claim 11, wherein the second package substrate further comprises a dummy pattern overlapping the fiducial mark in the vertical direction, and
wherein the dummy pattern and the second redistribution structure comprise a same material.

15. The semiconductor package of claim 11, wherein the fiducial mark is separated from the second redistribution structure by at least 100 mm in a plan view.

16. The semiconductor package of claim 11, wherein the fiducial mark has a shape other than a circular planar shape and a regular polygonal planar shape.

17. A semiconductor package comprising:
a first package substrate comprising a first redistribution structure;
a first semiconductor chip provided on the first package substrate;
a plurality of conductive posts provided around the first semiconductor chip on the first package substrate;
a second package substrate provided on the first semiconductor chip and electrically connected to the first package substrate through the plurality of conductive posts, the second package substrate comprising a second redistribution structure;
a plurality of upper surface pads provided on an upper surface of the second package substrate;
a plurality of dummy pads provided on the second package substrate, and provided outside the plurality of upper surface pads relative to a central portion of the second package substrate in a plan view, the plurality of dummy pads comprising an independent island shape separated from the second redistribution structure, and the plurality of dummy pads being separated from each other relative to the central portion of the second package substrate;
a third package substrate electrically connected to the second package substrate through a plurality of conductive connection terminals respectively provided on the plurality of upper surface pads; and
a second semiconductor chip provided on the third package substrate.

18. The semiconductor package of claim 17, wherein the second package substrate further comprises a dummy pattern overlapping the plurality of dummy pads in a vertical direction.

19. The semiconductor package of claim 17, wherein at least some of the plurality of dummy pads have different shapes.

20. The semiconductor package of claim 17, further comprising an underfill layer provided between the second package substrate and the third package substrate.
